(19) United States
(12) Patent Application Publication
(10) Pub. No.: US 2026/0369496 A1
(43) Pub. Date: Nov. 19, 2026

(54) AC BINARY INPUTS FOR INTELLIGENT ELECTRONIC DEVICES

(71) Applicant: Schweitzer Engineering Laboratories, Inc., Pullman, WA (US)

(72) Inventor: Brian James Peterson, Moscow, ID (US)

(73) Assignee: Schweitzer Engineering Laboratories, Inc., Pullman, WA (US)

(21) Appl. No.: 19/211,576

(22) Filed: May 19, 2025

(51) Int. Cl. H01H 47/00; G01R 19/165; H02M 7/06

(52) U.S. Cl. CPC H01H 47/001; G01R 19/16557; H02M 7/064

(57) ABSTRACT

A binary input detection system for protective intelligent electronic devices (IEDs) enables fast and reliable AC and DC voltage detection through a single, predetermined debounce period for both pickup and dropout events. The system may incorporate a rectifying circuit, a voltage comparator with hysteresis, and a debounce filter to ensure accurate signal detection and response in the presence of electrical noise, harmonics, and transient fluctuations. Eliminating separate pickup and dropout timers simplifies system design while enhancing detection speed. The methods and systems described herein employ user-programmable voltage levels and frequencies along with a controlled debounce period to ensure precise binary input response across various operating conditions.

### TECHNICAL FIELD

This disclosure relates to intelligent electronic devices (IEDs) in electrical power systems. Specific aspects of this disclosure relate to rectifiers, voltage comparators, debounce filters, and signal processing.

### BRIEF DESCRIPTION OF THE DRAWINGS

The written disclosure herein describes illustrative embodiments and examples that are nonlimiting and non-exhaustive. This disclosure references some of these embodiments, as depicted in the figures described below.

FIG. 1 illustrates an intelligent electronic device with sub-half-cycle binary input detection functionality, according to one embodiment.

FIG. 2 illustrates an example of a rectifying circuit for processing an AC voltage waveform, according to one embodiment.

FIG. 3 illustrates an example of an AC binary input path, according to one embodiment.

FIG. 4 illustrates an example of a voltage comparator operating in hysteretic mode, according to one embodiment.

FIG. 5A illustrates a graph of an AC voltage waveform, according to one embodiment.

FIG. 5B illustrates a graph of a full wave rectification, according to one embodiment.

FIG. 5C illustrates a graph of a rectified AC voltage waveform, according to one embodiment.

FIG. 5D illustrates a graph of voltage thresholds for a voltage comparator in hysteretic mode, according to one embodiment.

FIG. 5E illustrates a graph of a comparator output for a voltage comparator in hysteretic mode, according to one embodiment.

FIG. 6A illustrates a graphical depiction of assertion and de-assertion events of a voltage comparator in hysteretic mode, according to one embodiment.

FIG. 6B illustrates a graphical depiction of the assertion and de-assertion of a debounce filter with a single debounce delay, according to one embodiment.

FIG. 7 illustrates a graph of a debounce filter asserting, according to one embodiment.

FIG. 8 illustrates a graphical depiction of a rectified AC voltage waveform over a single cycle, according to one embodiment.

FIG. 9A illustrates a graph of a comparator output signal that fails to de-assert with a single debounce delay set to ½ cycle, according to one embodiment.

FIG. 9B illustrates a graph of a comparator output signal toggling with a single debounce delay set to ¼ cycle, according to one embodiment.

FIG. 9C illustrates a graph showing the relationship between a functional binary input detection system and a single debounce delay set to % cycle, according to one embodiment.

FIG. 10 illustrates a graph depicting the relationship between the rectified AC voltage waveform, comparator threshold levels, and debounce timing, according to one embodiment.

FIG. 11 illustrates a flow chart of a method to detect AC binary input signals in Intelligent Electronic Devices (IEDs), according to one embodiment.

### DETAILED DESCRIPTION

Binary input detection systems in intelligent electronic devices (IEDs), such as protective relays, commonly rely on a plurality of signal processing functions to reliably detect the pickup (assertion) or dropout (de-assertion) of an input voltage signal. For example, when an AC voltage waveform is applied to a binary input terminal, the system processes the waveform to filter out transient noise, ensuring that only sustained voltage changes trigger a binary state transition. To prevent erratic behavior due to voltage fluctuations, debounce filtering may be implemented, where the signal persists above or below a threshold for a defined period of time before the binary output state (e.g., binary output signal) changes.

Traditional binary input detection systems commonly utilize separate debounce timers for the assertion and de-assertion of AC voltage signals. These systems typically employ a short debounce delay, often around 2 milliseconds (ms), for pickup and a significantly longer debounce delay, around 10 ms, for dropout. This approach is intended to prevent false triggering due to transient noise while ensuring stable operation. However, maintaining two separate debounce delays increases complexity, requires additional programmable resources, and may introduce unnecessary delays in binary state transitions. The additional logic and processing needed for two debounce delays can impose restrictions on firmware design, requiring careful tuning of both timing parameters to prevent malfunctions in critical power protection applications. In systems where multiple binary inputs are in operation, the cumulative effect of these separate debounce timers can create unnecessary delays, especially in environments where rapid fault detection and response are essential to preventing damage to power system infrastructure.

While dual debounce timers offer stability, they also limit responsiveness and often increase operational overhead in protective relay applications. The need for separate pickup and dropout delays extends overall detection time, leading to slower system reactions in response to AC voltage fluctuations. IEDs are often deployed in high-voltage environments with dynamic electrical conditions, where fluctuating input voltages, transient disturbances, and harmonic interference can impact binary input accuracy and response. Existing systems relying on dual debounce timers can struggle to maintain reliability under these conditions, particularly if the dropout delay is excessively long. In environments with high electrical noise or varying AC frequencies, binary input systems may fail to assert properly or toggle unpredictably if the debounce delay timing is not correct. Furthermore, increased programmable logic resource usage can constrain system scalability and complicate the configuration, particularly in applications with multiple binary input ports. In large-scale installations, where numerous binary inputs are managed simultaneously, the inefficiencies of traditional debounce approaches become more pronounced, consuming additional processor resources to maintain accurate and timely voltage detection. The presently described systems and methods introduce a novel approach to AC voltage detection that enhances detection accuracy, minimizes processing overhead, and maintains stable operation across varying input conditions.

The presently described systems and methods implement a single, predetermined debounce period that governs both assertion and de-assertion of AC binary input signals (also referred to herein as AC voltage waveforms, AC waveforms, AC input signals, and AC input voltage signals), eliminating the need for multiple pickup and dropout debounce timers. A single predetermined debounce period (e.g., debounce delay, debounce delay period, predetermined debounce delay, and/or debounce time) also reduces the overall detection time of the binary input system. In various embodiments, a protective intelligent electronic device (IED) includes one or more screw terminals configured as binary input ports, allowing external voltage signals to be applied for detection and processing. An input voltage signal received at the binary input terminals may be in the form of either alternating current (AC) or direct current (DC) and can vary across a range of nominal voltages. Examples of possible AC voltages include 100 V, 110 V, 120 V, 140 V, 160 V, 200 V, 220 V, 230 V, and 240 V. In some embodiments, the applied AC voltage waveform may propagate at standard power system frequencies, including 50 Hz and 60 Hz.

According to various embodiments, a rectifying circuit may be coupled to the binary input terminals. The rectifying circuit may use a full-bridge rectifier to convert incoming AC input signals into a rectified AC output signal (e.g., rectified AC voltage waveform, rectified AC voltage, and/or rectified voltage signal), where both positive and negative half-cycles are transformed into a full-wave rectified signal. Rectification prevents polarity-dependent errors in AC input signals and enables the system to evaluate the input voltage consistently. Additionally, the rectifier enables the detection of DC input signals by maintaining signal integrity regardless of polarity.

Once the rectified AC voltage waveform (e.g., rectified AC voltage and/or rectified signal) is generated, it is processed by a voltage comparator. The voltage comparator may, for example, operate in hysteretic mode. In other embodiments, the voltage comparator may operate in hysteretic mode, midrange mode, greater than mode, lesser than mode, or a combination thereof. The voltage comparator evaluates the rectified signal against predefined upper and lower voltage thresholds. The upper threshold defines the voltage level at which the comparator output asserts, while the lower threshold establishes the level at which the comparator output de-asserts. By maintaining a hysteresis band between the two thresholds and with a target selection of the upper and lower comparator thresholds, the system prevents toggling of the output signal and generates a buffered comparator output, even in environments with electrical noise or transient fluctuations.

In various embodiments for power system protection and control, the pickup threshold for an AC signal is set at approximately 80% or higher of the rated root-mean-square (RMS) voltage.

V_{PU}=0.80×Vᵣₘₛ Equation 1

The upper threshold level for the voltage comparator, different from the pickup threshold of an AC signal, is selected to ensure that the binary inputs system reliably asserts when the rectified AC voltage reaches approximately 80% of the rated RMS voltage (e.g., 88 Vᵣₘₛ for a 110 V input voltage). Once an upper threshold has been set, the system may derive a dropout voltage V_{DO} as a function of the upper threshold and the RMS multiplier:

$${V}_{DO} = \frac{Upper Threshold}{\sqrt{2}} \qquad Equation 2$$

The lower threshold level for the voltage comparator is constrained to a value less than the upper threshold. Additionally, the lower threshold level may be greater than zero to generate a reliable comparator output.

In another embodiment, the voltage comparator output undergoes processing by a debounce filter that enforces the single predetermined debounce period. The debounce filter verifies that the comparator output is sustained for the duration of the debounce delay period before the binary output state is updated. The presently described system applies the same debounce delay to both assertion and de-assertion. In one embodiment, setting a single debounce delay with a value of ⅜ cycle of the AC voltage waveform is used to facilitate the consistent operation of the binary inputs.

The implementation of a single debounce delay period provides several advantages over traditional binary input detection systems. By setting the debounce time within an adequate range, the system avoids unnecessary toggling caused by an overly short debounce period while also preventing failed assertions due to an overly long debounce period. For example, when the debounce period is set to less than ¼ cycle, the binary input toggles at the AC waveform frequency, leading to faulty operation. Conversely, when the debounce period is set to greater than ½ cycle, the binary input fails to assert, as the zero-crossing of the AC waveform repeatedly resets a debounce filter counter before assertion.

In one embodiment, the debounce filter is implemented using a counter-based approach. A debounce filter counter increments while the voltage comparator output remains asserted and decrements when the comparator output is de-asserted. When the counter reaches the preset debounce delay period, the binary output state is updated. This approach leads to successful binary input detections of AC input signals. Alternatively, the debounce filter may also or alternatively use a different approach or a combination of approaches, including but not limited to shift register-basing and/or time-weighted averaging.

In various embodiments, the binary input system supports a dynamically configurable debounce delay period when operating in a DC input signal detection mode. This configuration allows a user to define a single voltage pickup and dropout time that operates as the debounce delay period, specifying the duration the comparator output remains asserted or de-asserted prior to initiating a binary input state transition.

Compatibility with various AC and DC input voltages allows for operational flexibility. The integration of a programmable gain amplifier (PGA) with the binary input terminals allows dynamic adjustment of the input signal amplitude before processing through the rectifying circuit. The PGA scales the signal according to the level of the input voltage signal. A PGA gain setting of 1 may be used for a 240 V AC signal, while a PGA gain setting of 2 may be applied for a 120 V AC signal. In various embodiments, the PGA may be automatically adjusted based on a measured amplitude of the waveform before generating the digital signal via the analog-to-digital converter.

In some embodiments, signal detection stability is further improved through sampling by a successive approximation register analog-to-digital converter (SAR ADC). Operating at a rate higher than the AC cycle frequency, the SAR ADC converts the analog voltage signal into a digital format for enhanced processing. Various alternative ADC devices and/or approaches may be utilized, including but not limited to, delta-sigma ADC devices. Furthermore, some embodiments may employ additional and/or alternative digital filtering methods, including but not limited to averaging and/or decimation filtering.

In some embodiments, decimation filtering systematically reduces the sampling rate of the analog-to-digital converter (ADC) through averaging, which reduces high-frequency noise impact on the binary input detection process. Lower-frequency signal components are consistently retained, and high-frequency noise is discarded.

An intelligent electronic device (IED) may refer to any microprocessor-based system designed to monitor, control, automate, and protect equipment within an electrical or industrial system. Examples of such devices include but are not limited to, programmable logic controllers (PLCs), bay controllers, motor relays, feeder relays, distance relays, voltage relays, directional relays, automation controllers, overcurrent relays, generator relays, voltage regulator controls, recloser controls, communication processors, computing platforms, remote terminal units (RTUs), breaker failure relays, protective relays, power management units, digital fault recorders, input and output modules, motor drives, programmable automation controllers, phasor measurement units (PMUs), supervisory control and data acquisition (SCADA) systems, intelligent power meters, and distribution automation controllers. Additionally, IEDs may function as controllers for wide-area monitoring systems (WAMS), remedial action schemes (RAS), or special protection schemes (SPS).

In various embodiments, binary inputs serve a fundamental role in maintaining the functionality of IEDs across the above applications. In protective relays, binary inputs may detect trip signals, generate breaker statuses, and/or execute auxiliary contact changes. In bay controllers, binary inputs may monitor interlocking conditions. In PLCs, binary inputs may be used for sensor control, limit switches, push buttons, and/or execution of programmed logic functions. Accurate binary input detection may be used in applications with rapid voltage state changes, ensuring reliable system performance across a plurality of industrial, safety, and utility environments.

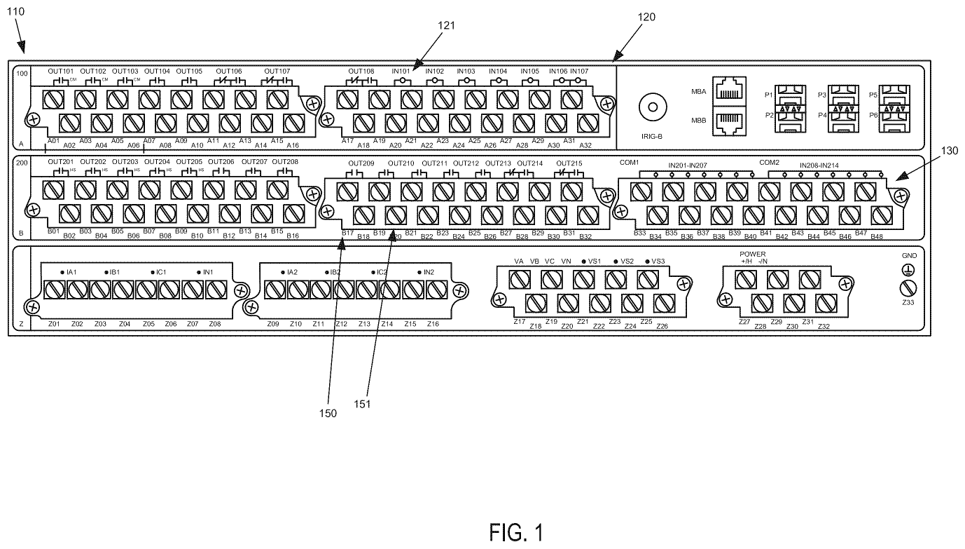

FIG. 1 illustrates an input panel of a protective intelligent electronic device (IED) 110, such as a relay or other protective device. The protective IED 110, as described herein, may be configured to receive and detect voltage signals applied by external sources. External sources may include but are not limited to, Battery Monitoring Systems, Uninterruptible Power Supplies (UPS), Voltage Sensors, Voltage Transformers, Resistance Temperature Detectors (RTD), Thermistors, Current Transformers (CTs) with Overcurrent Relays, Digital Fault Recorders (DFRs), Programmable Logic Controllers (PLCs), Remote Supervisory Control Systems (SCADA RTUs, DCS), and Breaker Auxiliary Contacts. External sources may also include motor protection devices that monitor the operating conditions of induction motors, synchronous motors, and variable frequency drive-controlled (VFD-controlled) motors. For transmission line applications, external sources may consist of line current differential relays, distance relays, capacitor bank controllers, voltage regulators, and transmission line monitoring systems.

In the illustrated embodiment, the protective IED 110 includes a set of binary inputs 120, each configured to detect the presence or absence of an applied voltage signal. Individual binary input 121 represents an example of a single binary input within the set of binary inputs 120. In this configuration, the binary input port for individual binary input 121 is implemented as a screw terminal; however, alternative input configurations may be utilized in other embodiments. A second set of binary inputs 130 is similarly configured to receive additional voltage signals, allowing the protective IED 110 to monitor multiple discrete events within a power system. In various embodiments, the binary input status may be used to detect a sustained voltage condition corresponding to a protective criterion, for which the IED 110 may issue a protective action command.

Each binary input in the set of binary inputs 120 and the second set of binary inputs 130 can detect both alternating current (AC) and direct current (DC) voltage waveforms. In some embodiments, the set of binary inputs 120 and the second set of binary inputs 130 may receive AC voltage signals at commonly used system frequencies, such as 50 Hz or 60 Hz, with nominal voltage levels that may include 100 V, 120 V, 208 V, 220 V, 230 V, 240 V, or 250 V AC, among others. In another embodiment, the set of binary inputs 120 and a second set of binary inputs 130 may detect DC control signals, such as 24 V, 48 V, 110 V, 125 V, 220 V, or 250 V DC, signals commonly used in substation automation systems for breaker status indication and control circuit monitoring. A voltage change at the binary input may result from various operating conditions, such as a breaker opening, a trip coil activation, or the loss of a control voltage. Upon detecting an assertion (pickup) or de-assertion (dropout) event at a given binary input, the protective IED 110 may execute predefined logic operations to generate a corresponding digital output response. For instance, individual binary input 121 may detect a dropout condition (e.g., loss of voltage signal) from a voltage transformer. The individual digital output at terminal 151 is part of the set of digital outputs 150. The individual digital output at terminal 151, which corresponds to individual binary input 121, is then triggered, which may activate an external alarm to notify system operators. In another embodiment, if individual binary input 121 detects an overvoltage condition that surpasses a predefined threshold, the digital output at terminal 151 may then issue a trip command to open a circuit breaker, thereby preventing damage to downstream electrical equipment.

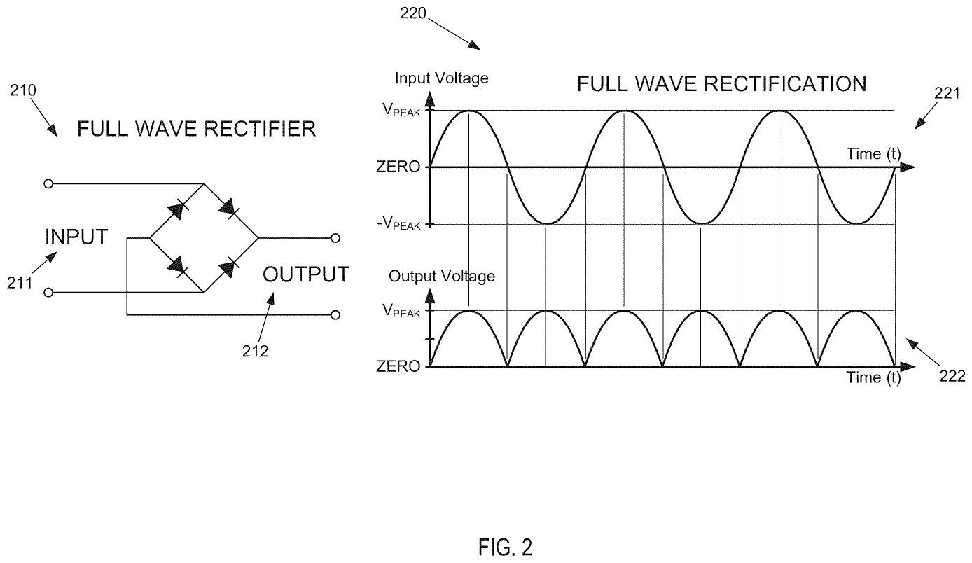

FIG. 2 illustrates an example of a rectifying circuit configured to process an AC voltage waveform received from a binary input, such as those in the set of binary inputs 120 and the second set of binary inputs 130. In this embodiment, a full-wave rectifier 210 is implemented to convert the AC input voltage signal into a rectified AC voltage waveform, ensuring that both the positive and negative half-cycles of the AC waveform are transformed into a full-wave rectified signal. An AC voltage waveform is applied at the input terminal 211, where it undergoes rectification through the diode bridge network of the full-wave rectifier 210. The processed signal is then output at terminal 212, generating a rectified AC voltage waveform. The graphical representation 220 illustrates the rectification process, where the input voltage waveform 221 corresponds to the sinusoidal AC signal applied at the input terminal 211, and the output voltage waveform 222 corresponds to the rectified signal observed at terminal 212. The rectified AC voltage waveform maintains the same peak voltage as the original AC signal but eliminates negative polarity by inverting the negative half-cycles, producing a waveform with only positive half-cycles. This conversion ensures that binary input detection remains independent of input polarity, allowing the system to process AC signals uniformly and enabling the detection of direct current (DC) signals of either polarity.

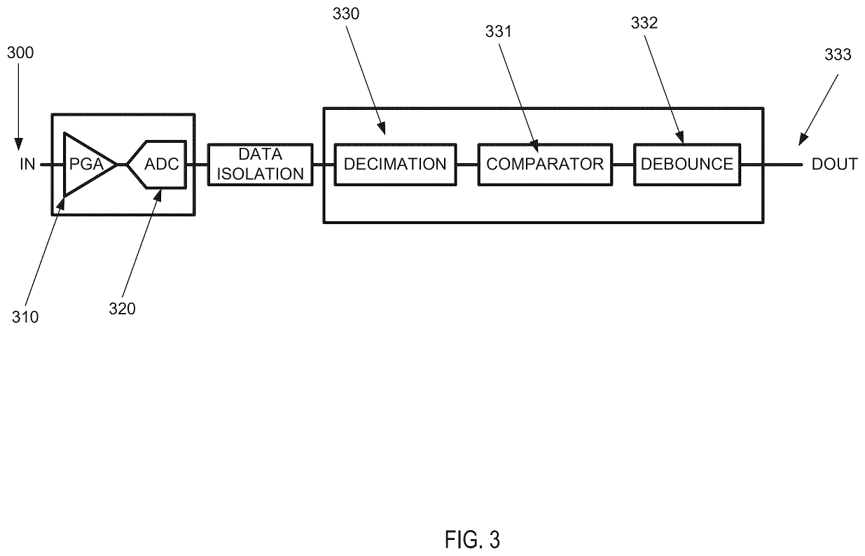

FIG. 3 illustrates an example of an AC binary input processing path, according to one embodiment. An input voltage signal 300 is received at terminal IN 310, where it is first processed by a programmable gain amplifier (PGA) to adjust the signal amplitude according to predefined gain settings. The amplified AC waveform is then converted into a digital signal using an analog-to-digital converter (ADC) 320, such as a Successive Approximation Register ADC (SAR ADC). The digital signal is then passed through a decimation filter 330, reducing the sampling rate while averaging multiple samples.

Following decimation, the processed signal is evaluated by a voltage comparator 331 (e.g., operating in hysteretic mode or another mode). With the voltage comparator 331 operating in hysteretic mode, the voltage comparator 331 operates with an instantaneous output to determine whether the input voltage exceeds predefined upper or lower threshold values. The comparator output is then subjected to a debounce filtering stage 332, ensuring that transient fluctuations do not trigger false state changes. Employing a single debounce delay, the same time qualification can be applied to both rising and falling edge transitions, reducing the overall debounce time and processing requirements. The binary output status is generated based on the processed signal and is made available via a DOUT pin 333 for external monitoring or control applications.

A graph of the ADC output (e.g., the digital signal) overlayed on the comparator output illustrates the instantaneous function and output of a voltage comparator operating in hysteretic mode.

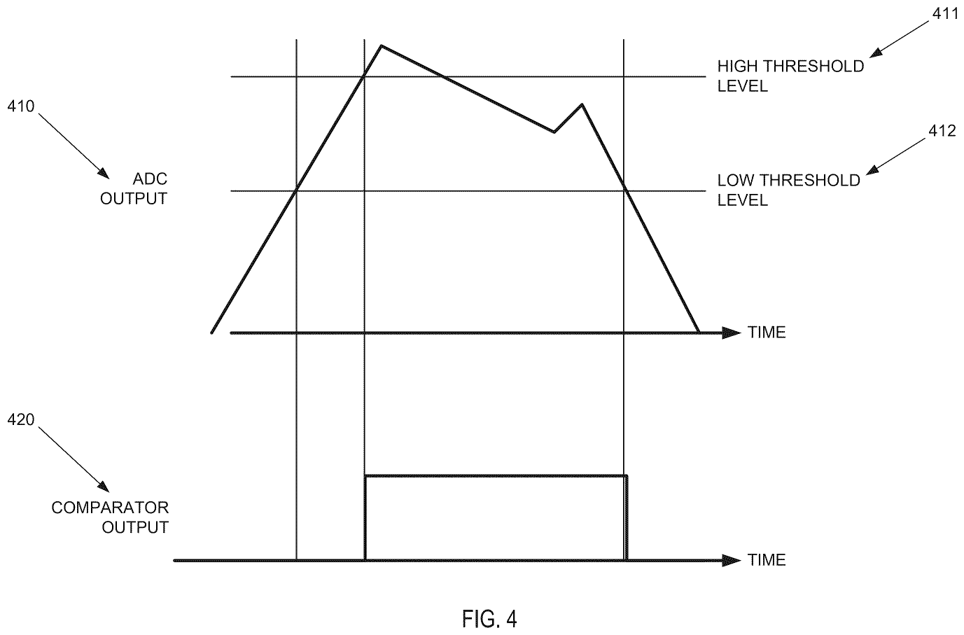

FIG. 4 illustrates the relationship between an ADC output signal 410 and the corresponding comparator output 420 as the input voltage fluctuates over time. The region between the upper threshold level 411 and the lower threshold level 412 defines a hysteresis band. The input signal crosses a predefined upper boundary (e.g., upper threshold and/or upper threshold level) or lower boundary (e.g., lower threshold and/or lower threshold level) before the comparator state changes. For example, if the upper threshold level 411 is set to 59 V, and the lower threshold level 412 is set to 27 V, the comparator output does not assert until the ADC output 410 exceeds 59 V, at which point the comparator output transitions to 1 (asserted). Once asserted, the output remains at 1 if the ADC output is above 27 V. If the ADC output falls below 27 V, the comparator output de-asserts (transitions back to 0) and does not assert again until the ADC output surpasses 59 V.

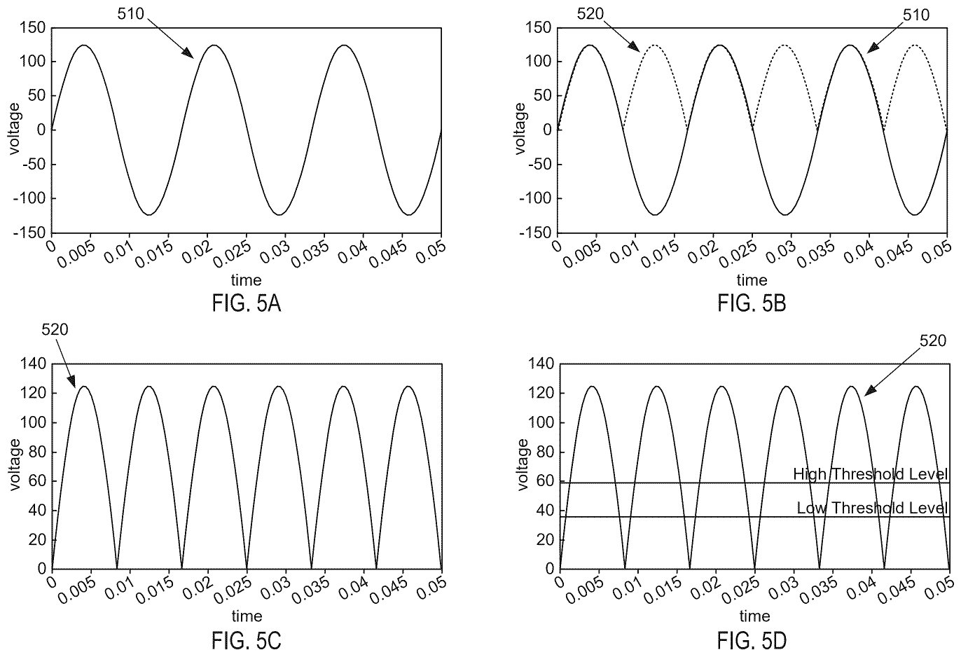

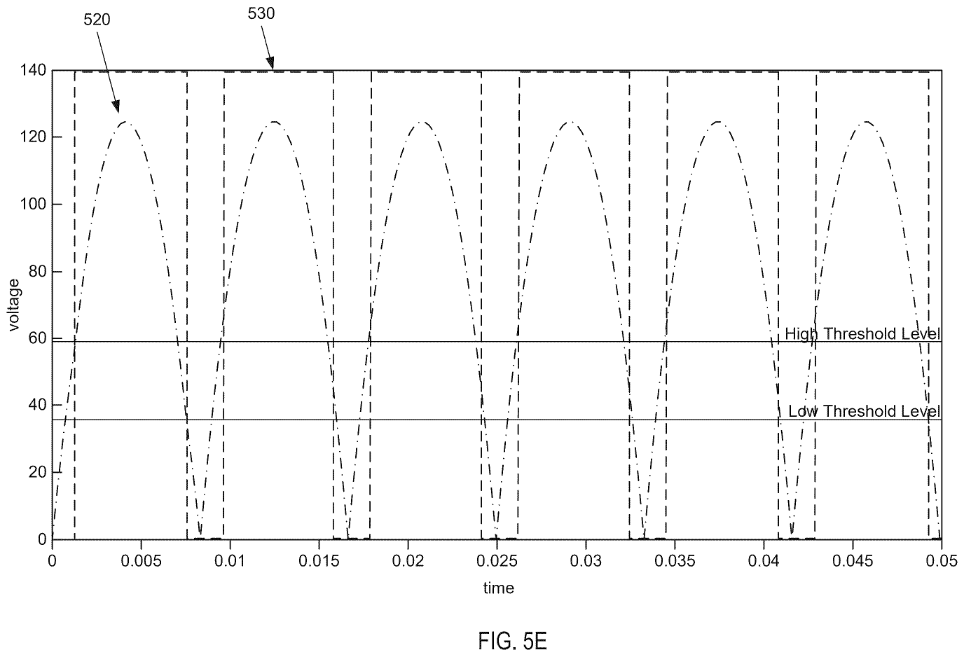

FIGS. 5A through 5E illustrate the processing stages of an AC voltage waveform 510 applied to a binary input and its transformation through rectification, threshold comparison, and comparator output generation. FIG. 5A depicts an AC voltage waveform 510 applied at the binary inputs before rectification. The dotted line of FIG. 5B represents the rectified AC voltage waveform 520, where the negative half-cycles of the AC voltage waveform 510 have been inverted to produce a full-wave rectified signal. The original AC voltage waveform remains on the graph to provide a contextual reference, illustrating the transformation from the alternating input to the rectified signal. FIG. 5C provides a rescaled graphical depiction of rectified AC voltage waveform 520, demonstrating the rectified signal that serves as the input for the comparator stage. FIG. 5D introduces the upper and lower threshold levels of the voltage comparator superimposed on rectified AC voltage waveform 520. FIG. 5E illustrates the comparator output 530, emphasizing the direct correlation between rectified AC voltage waveform 520, voltage threshold comparison, and the binary state transitions.

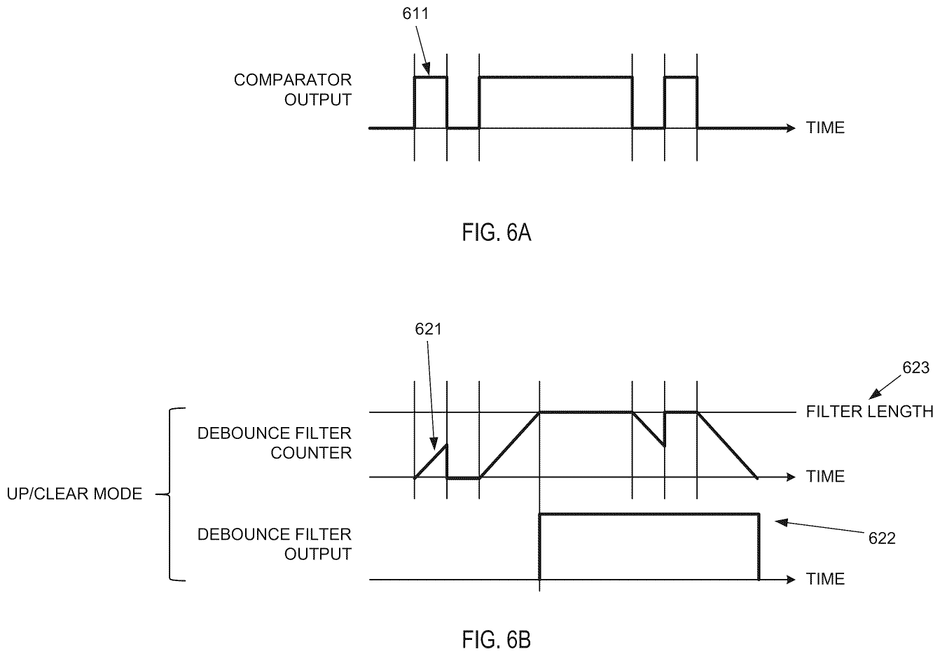

FIG. 6A illustrates the instantaneous behavior of a voltage comparator operating in hysteretic mode. The rising and falling edge transitions of the comparator output 611 indicate assertion and de-assertion events as the comparator responds to upper or lower threshold crossings in the rectified AC voltage waveform.

FIG. 6B illustrates the operation of the debounce filter that follows the voltage comparator. The debounce filter functions by incrementing a debounce filter counter 621 while the comparator output 611 is asserted and decrementing while the comparator output is de-asserted. The debounce filter length 623 denotes the single predetermined debounce period, a function of the original voltage waveform cycle, and a value between ¼ and ½. For example, the debounce filter counter may increment every 20 microseconds (μs) while the comparator output remains high. If the comparator output transitions low before the counter reaches the debounce filter length 623, the counter is cleared to zero, preventing assertion. If the comparator output remains high long enough for the counter to reach the debounce filter length 623, the debounce filter output 622 is asserted.

Once asserted, the debounce filter counter 621 switches to a decrementing mode when the comparator output transitions low. At this point, the debounce filter counter begins decrementing every 20 μs until either the counter reaches zero or the comparator output transitions high. If the comparator output remains low long enough for the counter to reach zero, the debounce filter output 622 is de-asserted. If the comparator output transitions high before the counter reaches zero, the debounce filter counter is reset to the debounce filter length 623, and the debounce filter output remains asserted. The debounce filter ensures that only sustained transitions in the comparator output lead to changes in the binary input state.

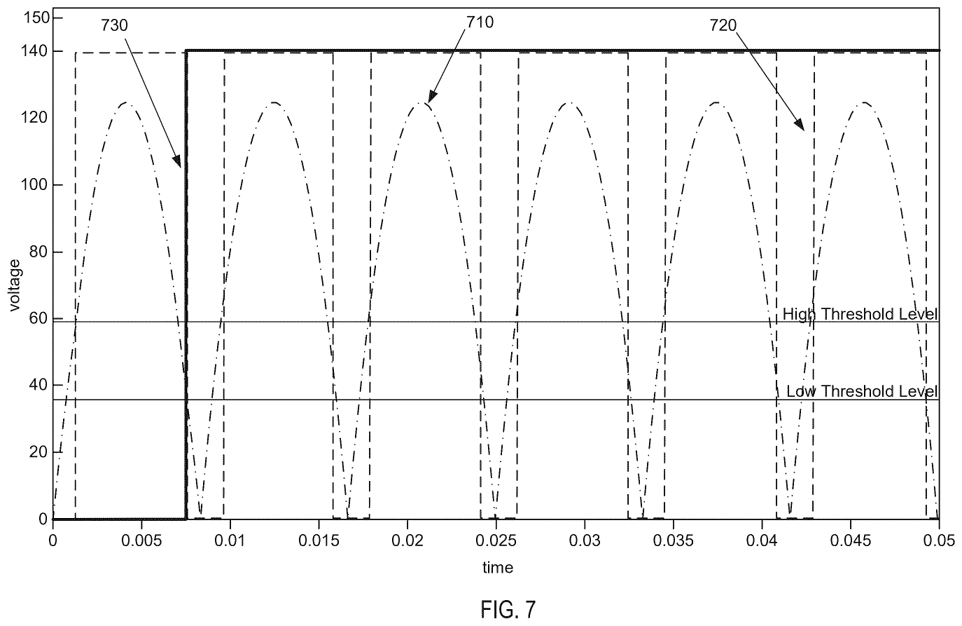

FIG. 7 illustrates the behavior of the debounce filter output 730 in response to the comparator output signal 720, which is generated based on the rectified AC voltage waveform 710, according to one embodiment. This figure emphasizes the consequences of selecting an overly long debounce delay, such as a ½ cycle, leading to data loss and failure to detect the AC waveform.

In this embodiment, the debounce filter initially asserts high due to a phase offset in the rectified AC voltage waveform. However, the debounce filter remains in a permanently asserted state for the rest of the period. Once the filter output is asserted, the debounce filter enters a decrement mode, as its value has reached the filter length. Upon the voltage waveform crossing the lower threshold, the comparator output de-asserts, and the debounce counter begins to decrement. The debounce filter waits for the debounce counter to decrement for the duration of the debounce delay, in this example, a ½ cycle, before it can de-assert.

However, due to the overly long debounce period of ½ cycle, the debounce counter is unable to reach zero before the voltage waveform crosses the upper threshold level. The debounce counter resets to the debounce delay value, and the debounce filter output remains asserted. As the AC waveform never remains above the upper threshold or below the lower threshold for a full debounce period of ½ cycle, the debounce filter continuously resets without completing a valid de-assertion event, and the binary input remains permanently asserted. This failure mode introduces operational risks that may lead to improper triggering of overvoltage protections, failure to detect undervoltage conditions, or the inability to recognize loss-of-phase events.

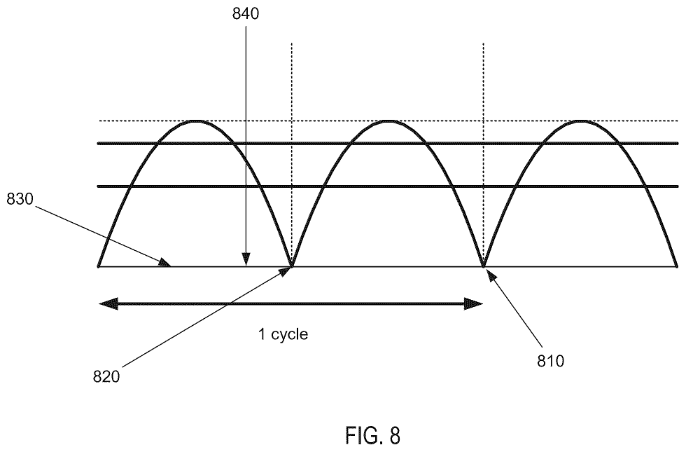

FIG. 8 illustrates a graphical depiction of a rectified AC voltage waveform, used to demonstrate the impact of different debounce delay durations, including ¼ cycle, 3% cycle, and ½ cycle, on binary input detection. The figure highlights how selecting the appropriate debounce period affects assertion and de-assertion behavior in a binary input detection system.

The length of one cycle 810 of an AC voltage waveform is shown. As a result of the full-wave rectification, the signal repeats itself every ½ cycle, denoting that every ½ cycle, there is both a zero crossing and a voltage peak (Vₚₑₐₖ). A complete cycle consists of two alternating half-cycles. The duration of a full cycle is determined by the frequency of the AC voltage waveform. For instance, at 60 Hz, a full cycle lasts 16.67 ms, while at 50 Hz, the cycle lasts 20 ms. Consequently, there is a repeating signal approximately every 8.335 ms. The ½ cycle point 820 marks a zero crossing, where the rectified AC voltage briefly reaches zero before the next peak begins. A debounce period set to ½ cycle or longer stops the binary input from asserting, as every half-cycle contains a zero crossing. It is generally known that for non-zero thresholds for a voltage comparator in hysteresis, it is impossible to guarantee that the voltage will remain above the upper threshold for the duration of ½ cycle. The zero crossing forces the voltage comparator to transition low periodically, resetting the debounce filter counter to zero before assertion can occur. Since the debounce filter uses a sustained high signal for the full debounce period, the debounce filter output never asserts.

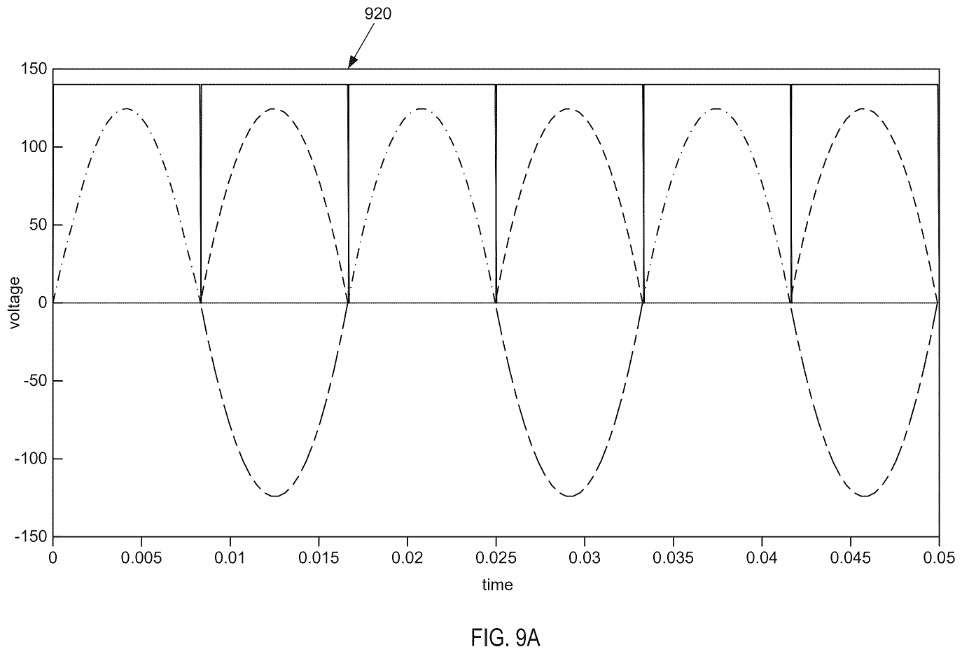

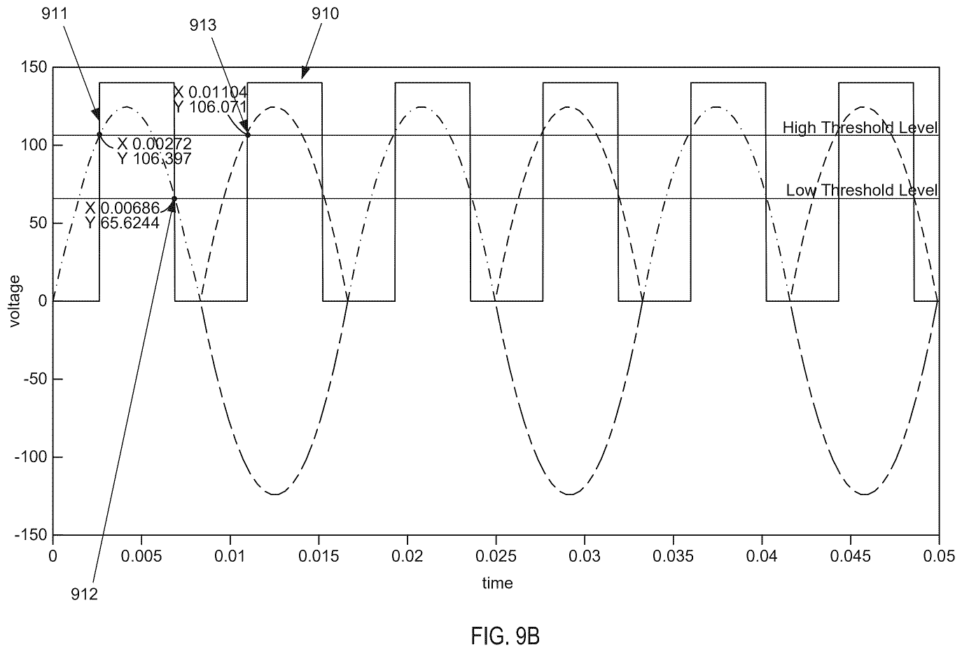

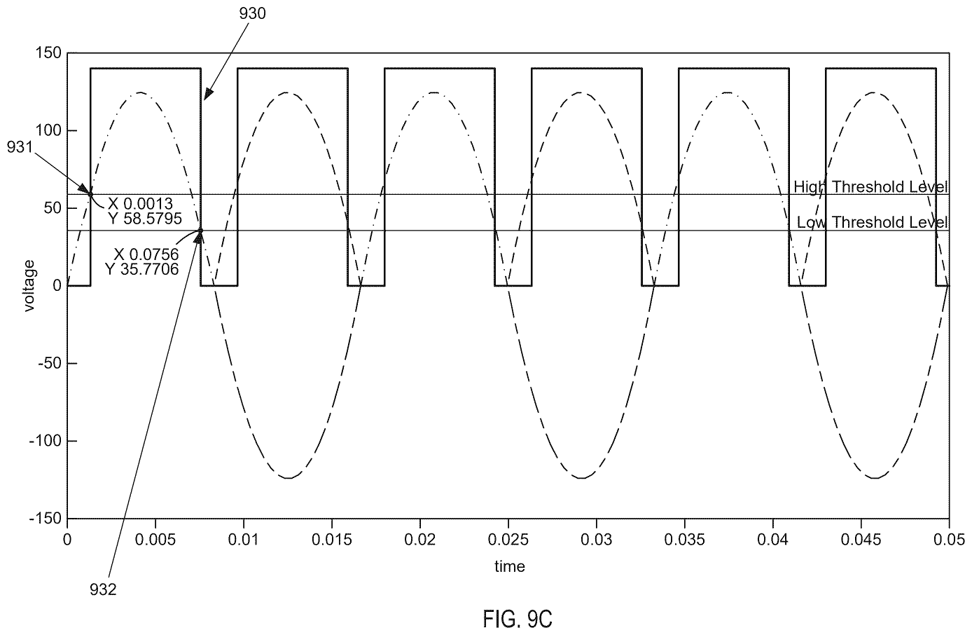

FIG. 9A illustrates this condition, where the comparator output 920 is in a constant assertion state, with ½ cycle pulses that drop below the threshold level for an unmeasurable amount of time. This restricts the binary inputs to an unchanging and non-functioning asserted state.

A ¼ cycle point 830, if selected as a debounce period, causes constant binary input toggling or rapid and repeated switching between the asserted and de-asserted states.

FIG. 9B illustrates this condition, where comparator output 910 alternates between high and low. The toggling occurs as the distance between the comparator assertion event 911 and the comparator de-assertion event 912 is identical to the debounce period, or ¼ cycle. A second comparator assertion event 913 occurs after another ¼ cycle. The debounce filter output responds by switching from high to low every ¼ cycle. This event is consistent with any debounce period of ¼ cycle or less.

A ⅜ cycle point 840 represents a conservative and functional debounce period.

FIG. 9C illustrates an example of the separate components of a functioning AC binary inputs system. The comparator output 930 transitions high as a rectified AC voltage waveform at 60 Hz and crosses the upper threshold level 931 at 1.3 ms and 58.5795 V. The comparator output remains asserted for approximately ¾ of the rectified AC voltage waveform's ½ cycle. At 7.56 ms, the AC voltage waveform crosses the lower threshold 932 at 35.7706 V, and the comparator output transitions low, remaining low for approximately ¼ of the rectified AC voltage waveform's ½ cycle. The debounce period is defined by:

$${D}_{p} = 0.375 \times \frac{1}{f} \qquad Equation 3$$

Using a frequency of 60 Hz for the AC voltage waveform, Dₚ≈6.25 ms. Consequently, the time difference between the comparator assertion and de-assertion events is equivalent to the debounce period. As the comparator was asserted for the entire duration of the debounce period, the binary input state transitions high at 7.56 ms. The time the voltage waveform spends under the lower threshold is much less than the debounce period, leaving the debounce filter output asserted for the duration that the waveform propagates. An example of an event that could cause the debounce filter output to de-assert is a voltage signal dropout, its value determined by Equation 2.

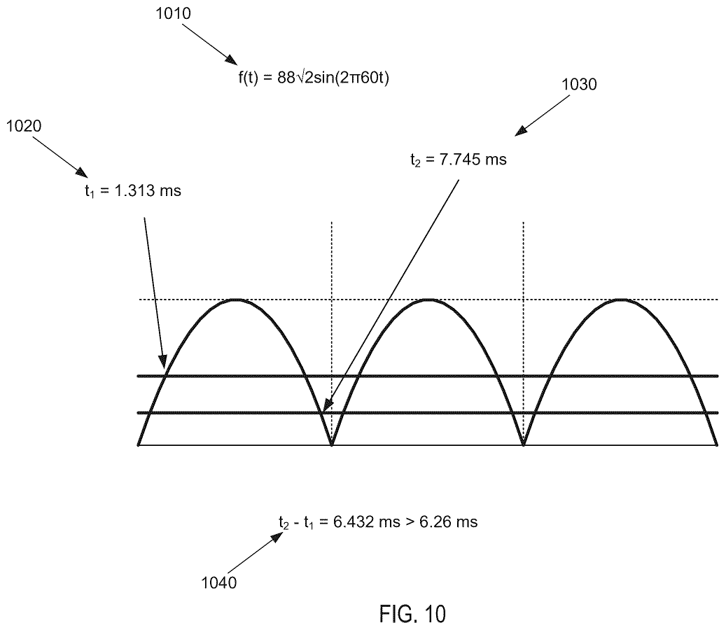

FIG. 10 illustrates another embodiment of the behavior of a rectified AC voltage waveform with respect to comparator threshold levels, demonstrating the debounce timing to determine stable assertion and de-assertion of a binary input detection system, according to one embodiment. The figure highlights the time the rectified AC voltage waveform crosses the voltage comparator's upper threshold at t₁ 1020. Additionally, the figure illustrates the time the rectified AC voltage waveform crosses the voltage comparator's lower threshold at t₂ 1030. The system applies a single debounce period set to 3% of a 60 Hz AC voltage waveform (e.g., debounce period Dₚ) to detect pickup and dropout events. A sinusoidal voltage function 1010 represents an AC voltage waveform with an RMS voltage of 88 V and a frequency of 60 Hz. The instantaneous voltage of this waveform is given by:

f(t)=Vᵣₘₛ\sqrt{2} sin(2πft) Equation 4

For this embodiment, the instantaneous voltage of a rectified AC voltage waveform is given by:

f(t)=88\sqrt{2} sin(2π60t) Equation 5

The amplitude (88\sqrt{2}) of the equation above is derived from the pickup voltage of 88 Vᵣₘₛ, or the solution of Equation 1 applied to a 110 V AC voltage waveform at 60 Hz.

At t₁ 1020, the voltage comparator output is asserted, and the debounce filter counter begins incrementing from a predetermined threshold low count value. The debounce filter counter increments until either (i) it reaches a threshold high count value equal to or greater than the debounce period Dₚ or (ii) the voltage comparator de-asserts. If the voltage comparator de-asserts before the debounce filter counter reaches the threshold high count value, the debounce filter counter is reset to the predetermined threshold low count value. In this embodiment, the comparator output de-asserts at time t₂ 1030, and the debounce filter counter decrements until either (i) it reaches a threshold low count value or (ii) the voltage comparator asserts. If the voltage comparator asserts before the debounce filter counter reaches the threshold low count value, the debounce filter counter is reset to the threshold high count value.

The difference in time 1040 between t₁ 1020 and t₂ 1030 is evaluated against the debounce period Dy threshold and found to be greater. This difference in time 1040 illustrates a successful AC voltage pickup that is attained immediately before the AC voltage waveform exceeds 88 Vᵣₘₛ, the exact moment occurring just before t₂ 1030.

In some embodiments, predefined upper and lower threshold values corresponding to certain AC system voltages and frequencies may be stored in registers configured to ensure compatibility across a plurality of environments and conditions. For example, in a 120 V AC, 60 Hz system, the upper threshold may be set to 72 ADC counts (≈54 V), whereas in a 240 V AC, 50 Hz system, the upper threshold may be 76 ADC counts (≈114 V). These values facilitate the reliable operation of AC digital inputs across various intelligent electronic devices (IEDs), analog-to-digital converters (ADCs), microcontrollers, and other processing or control hardware, including but not limited to these technologies

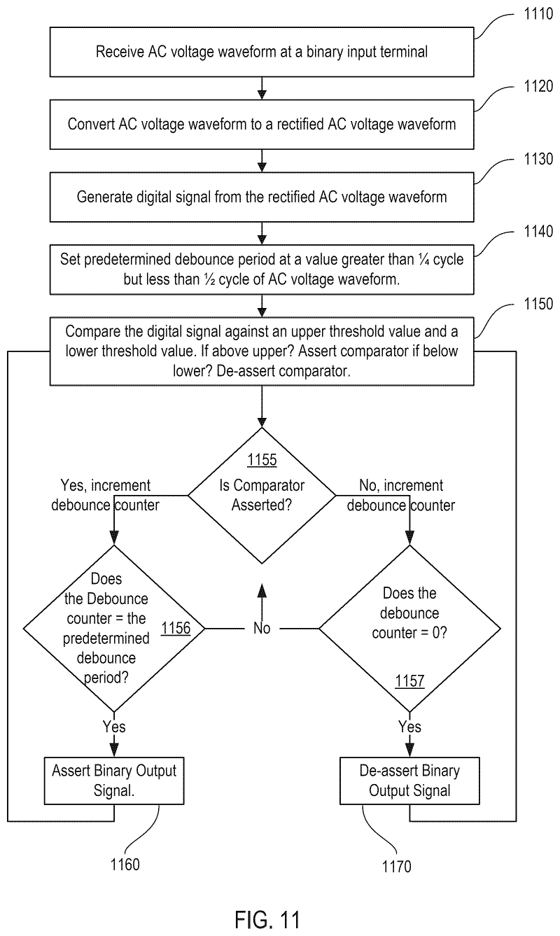

FIG. 11 illustrates a flowchart of a method for detecting binary input signals in an intelligent electronic device (IED) within an electrical power system. The method facilitates the processing of an alternating current (AC) voltage waveform, ensuring accurate assertion and de-assertion of a binary output signal using a voltage comparator in hysteretic mode and a debounce filter. The illustrated method may be executed by a protective relay or another intelligent electronic device.

The method begins with receiving an AC voltage waveform at a binary input terminal 1110. The binary input terminal is configured to receive an AC voltage waveform from an external power system source, such as a voltage transformer or a breaker auxiliary contact. Upon receiving the AC waveform, the system converts the AC voltage waveform into a rectified AC voltage waveform 1120 using a rectifying circuit. The rectified signal ensures that the binary input detection process operates independently of the polarity of the input voltage.

The rectified AC waveform is then converted into a digital signal 1130 using an analog-to-digital converter (ADC), enabling subsequent digital processing and threshold evaluation. Once digitized, the system sets a predetermined debounce period 1140, wherein the debounce period is defined within a range greater than ¼ cycle and less than ½ cycle of the AC voltage waveform. The debounce period prevents transient oscillations from triggering premature state changes in the binary input signal.

The digital signal is then compared against an upper threshold value and a lower threshold value 1150 using a voltage comparator operating in hysteretic mode. If the digital signal exceeds the upper threshold, the comparator output is asserted. If the digital signal falls below the lower threshold, the comparator output is de-asserted. This hysteresis prevents rapid toggling near the threshold boundary.

The system then evaluates whether the comparator output is asserted 1155. If the comparator output is not asserted, the system decrements the debounce counter 1157 to track the duration of de-assertion. The system then determines whether the debounce counter has reached zero 1157. If the debounce counter equals zero, the system de-asserts the binary output signal 1170 to reflect the absence of a valid AC voltage input. However, if the debounce counter has not yet reached zero, the system continues decrementing the counter while monitoring the comparator output.

If the comparator output is asserted 1155, the system increments the debounce counter. The system then determines whether the debounce counter has reached the predetermined debounce period 1156.

If the debounce counter has reached the debounce period, the system asserts the binary output signal 1160, indicating that the AC voltage waveform has been detected for a sufficient duration.

If the debounce counter has not yet reached the threshold debounce period, the system continues incrementing the counter while monitoring the comparator output.

The method ensures that the upper threshold value is defined in accordance with the predetermined debounce period to guarantee proper assertion of the binary output signal. The selection of the upper threshold influences the system's sensitivity to AC voltage fluctuations and improves resiliency to interference.

In some embodiments, the debounce period and comparator threshold values may be programmable via firmware registers, allowing adaptation to different power system configurations. Additionally, the system may implement adaptive debounce algorithms or machine-learning-based event classification to further enhance accuracy in noisy environments.

It is appreciated that the steps outlined in FIG. 11 may be executed in hardware, firmware, or software within an IED. In some embodiments, parallel processing may be used to monitor multiple binary input channels simultaneously, enabling advanced monitoring and automation capabilities. The disclosed method may be integrated into protective relays, automation controllers, substation monitoring devices, and industrial power management systems that use AC signal detection.

It is appreciated that two or more of the systems, subsystems, components, modules, etc., that are described herein may be combined as a single system, subsystem, module, or component. Moreover, many of the systems, subsystems, components, and modules may be duplicated or further divided into discrete systems, subsystems, components, or modules to perform subtasks of those described herein. Any of the embodiments described herein may be combined with any combination of other embodiments described herein.

The components of some of the disclosed embodiments are described and illustrated in the figures herein. Many portions thereof could be arranged and designed in a wide variety of different configurations. Furthermore, the features, structures, and operations associated with one embodiment may be applied to or combined with the features, structures, or operations described in conjunction with another embodiment. In many instances, well-known structures, materials, or operations are not shown or described in detail to avoid obscuring aspects of this disclosure. Many of the illustrations are provided in a block diagram format to illustrate a general configuration and may not be drawn to scale. The right to add any described embodiment or feature to any one of the figures and/or as a new figure is explicitly reserved.

This disclosure has been made with reference to various examples and embodiments, including the best mode. However, those skilled in the art will recognize that changes and modifications may be made to the exemplary embodiments without departing from the scope of the present disclosure. While the principles of this disclosure have been shown in various embodiments, many modifications of structure, arrangements, proportions, elements, materials, and components may be adapted for a specific environment and/or operating requirements without departing from the principles and scope of this disclosure. These and other changes or modifications are intended to be included within the scope of the present disclosure, along with every permutation of the claims filed herewith.

What is claimed:

1. A binary input detection system for an intelligent electronic device (IED) in an electrical power system, comprising:
a binary input terminal configured to receive an alternating current (AC) voltage waveform;
a rectifying circuit to convert the AC voltage waveform into a rectified AC voltage waveform;
an analog-to-digital converter (ADC) configured to generate a digital signal representative of the rectified AC voltage waveform;
a voltage comparator operating in hysteretic mode and configured to:
compare the digital signal against an upper threshold value and a lower threshold value,
assert a comparator output signal in response to the digital signal exceeding the upper threshold value, and
de-assert the comparator output signal in response to the digital signal being less than the lower threshold value; and
a debounce filter to generate a binary output signal by debouncing the comparator output signal using a single debounce period between ¼ cycle and ½ cycle of the AC voltage waveform.

2. The binary input detection system of claim 1, wherein the binary input terminal is further configured to detect direct current (DC) input voltage signals.

3. The binary input detection system of claim 2, wherein the rectifying circuit comprises a full-bridge rectifier configured to detect DC input voltage signals of either polarity.

4. The binary input detection system of claim 1, wherein the single debounce period is dynamically configurable.

5. The binary input detection system of claim 1, further comprising a Programmable Gain Amplifier (PGA) configured to adjust a gain of the AC voltage waveform.

6. The binary input detection system of claim 1, wherein the debounce filter is further configured to:
increment a debounce counter while the comparator output signal remains asserted;
assert the binary output signal when the debounce counter reaches a threshold high count value;
decrement the debounce counter while the comparator output signal remains de-asserted; and
de-assert the binary output signal when the debounce counter reaches a threshold low count value.

7. The binary input detection system of claim 1, wherein the system is further configured to detect AC voltage waveforms at frequencies of at least one of (i) 50 Hz and (ii) 60 Hz.

8. The binary input detection system of claim 7, wherein the debounce filter dynamically adjusts the single debounce period based on the frequency of the detected AC voltage waveform.

9. The binary input detection system of claim 1, wherein the single debounce period is set to 3% cycle of the AC voltage waveform.

10. The binary input detection system of claim 1, further comprising a decimation filter to improve signal stability and reduce noise.

11. The binary input detection system of claim 1, wherein the upper threshold value is selected as a predetermined fraction of a nominal root-mean-square (RMS) input voltage, and the lower threshold value is selected such that the voltage comparator maintains a hysteresis band to prevent toggling due to voltage fluctuations.

12. A method for detecting binary input signals for an intelligent electronic device (IED) in an electrical power system, comprising:
receiving, via a binary input terminal, an alternating current (AC) voltage waveform at a binary input terminal;
converting, via a rectifying circuit, the AC voltage waveform into a rectified AC voltage waveform;
generating, via an analog-to-digital converter (ADC), a digital signal representing the rectified AC voltage waveform;
comparing, via a voltage comparator operating in hysteretic mode, the digital signal against an upper threshold value and a lower threshold value to selectively assert a comparator output signal in response to the digital signal exceeding the upper threshold value, and de-assert the comparator output signal in response to the digital signal falling below the lower threshold value; and
generating, via a debounce filter, a binary output signal by:
using a single debounce period between ¼ cycle and less than ½ cycle of the AC voltage waveform,
incrementing a debounce counter while the comparator output signal remains asserted,
asserting the binary output signal upon the debounce counter reaching a threshold high count value,
decrementing the debounce counter while the comparator output signal remains de-asserted, and
de-asserting the binary output signal upon the debounce counter reaching a threshold low count value.

13. The method of claim 12, further comprising receiving, via the binary input terminal, a direct current (DC) input voltage signal.

14. The method of claim 13, further comprising receiving, from a user, a single pickup and dropout time for DC input voltage signal detection.

15. The method of claim 13, wherein the rectifying circuit comprises a full-bridge rectifier configured to detect DC input voltage signals of either polarity.

16. The method of claim 12, wherein the single debounce period is 38 cycle of the AC voltage waveform.

17. The method of claim 12, wherein the single debounce period is dynamically configurable based on a user-defined AC voltage waveform level and frequency.

18. The method of claim 12, wherein receiving the AC voltage waveform further includes passing the waveform through a programmable gain amplifier that is automatically adjusted based on a measured amplitude of the waveform before generating the digital signal via the analog-to-digital converter.

19. A protective device in an electrical power system, comprising:
a binary input terminal configured to receive an alternating current (AC) voltage signal from a monitored component in an electrical power system;
a rectifying circuit coupled to the binary input terminal, the rectifying circuit configured to generate a rectified AC voltage signal from the AC voltage signal;
an analog-to-digital converter (ADC) configured to produce a digital measurement of the rectified AC voltage signal;
a voltage comparator operating in hysteretic mode, the voltage comparator configured to:
compare the digital measurement against an upper threshold level and a lower threshold level,
assert a comparator output signal when the digital measurement exceeds the upper threshold level, and
de-assert the comparator output signal when the digital measurement falls below the lower threshold level;
a debounce filter configured to receive the comparator output signal and generate a binary input status signal by applying a single debounce period of more than one-quarter cycle and less than one-half cycle of the AC voltage signal for both assertion and de-assertion of the binary input status signal; and
a protection controller communicatively coupled to the debounce filter, the protection controller being configured to:
detect, via the binary input status signal, a sustained voltage condition corresponding to a protective criterion, and
issue a protective action command in response to the sustained voltage condition.

20. The device of claim 19, wherein the single debounce period is approximately three-eighths (⅜) of one cycle of the AC voltage signal.
